(19) United States
(12) Patent Application Publication
(10) Pub. No.: US 2012/0273042 A1
(43) Pub. Date: Nov. 1, 2012

(54) METHOD FOR IMPROVING THE QUALITY OF A TUNNEL JUNCTION IN A SOLAR CELL STRUCTURE

(76) Inventors: Xing-Quan Liu, Arcadia, CA (US); Christopher M. Fetzer, Valencia, CA (US); Daniel C. Law, Arcadia, CA (US)

(21) Appl. No.: 13/098,122

(22) Filed: Apr. 29, 2011

(51) Int. Cl. H01L 31/0687; H01L 31/18; H01L 31/02

(52) U.S. Cl. 136/259; 136/252; 438/93; 257/E31.019

(57) ABSTRACT

A method of forming a tunnel junction in a solar cell structure alternates between depositing a Group III material and depositing a Group V material on the solar cell structure.

### GOVERNMENT LICENSE RIGHTS

The invention was made with Government support under Contract Number FA9453-09-C-0373 awarded by the Department of Defense and DOE-DE FC36-0760170 awarded by the Department of Energy. The Government has certain rights in this invention.

### BACKGROUND

Embodiments of this disclosure relate generally to multiple junction solar cell structures, and more particularly, to a method for improving the quality of tunnel junctions in multiple junction solar cell structures.

Solar photovoltaic devices are devices which are able to convert solar radiation into usable electrical energy. Solar energy created through photovoltaic devices is the main source of power for many spacecraft. Solar photovoltaic devices are also becoming an attractive alternative for power generation for home, commercial, and industrial use since solar energy is environmentally friendly and renewable.

In multiple junction solar cell structures for concentrator photovoltaic application, tunnel junctions in between individual solar may play an important role in determining the efficiency of the solar cell structure. One way to increase the efficiency of the solar cells may be to improve the tunnel junction material quality and therefore the material quality of the layers grown on the tunnel junction, meanwhile to increase tunneling current from the tunnel junctions. Further, the tunnel junction needs to be transparent enough to allow light to pass through for underneath solar cells to absorb.

Therefore, it would be desirable to provide a system and method that overcomes the above problems.

### SUMMARY

A method of forming a tunnel junction in a solar cell structure comprises depositing a Group III material; and depositing a Group V material after deposition of said Group III material.

A method of forming a tunnel junction in a solar cell structure comprises alternating between depositing a Group III material and depositing a Group V material on the solar cell structure.

A photovoltaic device has a substrate. A first solar cell device is positioned above the substrate. A contact is positioned above the first solar cell. A tunnel junction is formed between the first solar cell and the contact. The tunnel junction is formed by migration-enhanced epitaxial (MEE).

The features, functions, and advantages can be achieved independently in various embodiments of the disclosure or may be combined in yet other embodiments.

### BRIEF DESCRIPTION OF THE DRAWINGS

Embodiments of the disclosure will become more fully understood from the detailed description and the accompanying drawings, wherein:

FIG. 1 is a simplified block diagram of a solar cell structure which may use a migration-enhanced epitaxial method to form the tunnel junction;

FIG. 2 is a timing diagram of a migration-enhanced epitaxial flow sequence during formation of the tunnel junction;

FIG. 3 is a flow chart showing a migration-enhanced epitaxial flow sequence during formation of the tunnel junction;

FIG. 4 shows the light I-V (LIV) performance of a migration-enhanced epitaxial grown GaInP tunnel junction at high temperature (HT) and conventional epitaxy grown GaInP tunnel junction (TuJn) at same temperature in a test structure.

### DETAILED DESCRIPTION

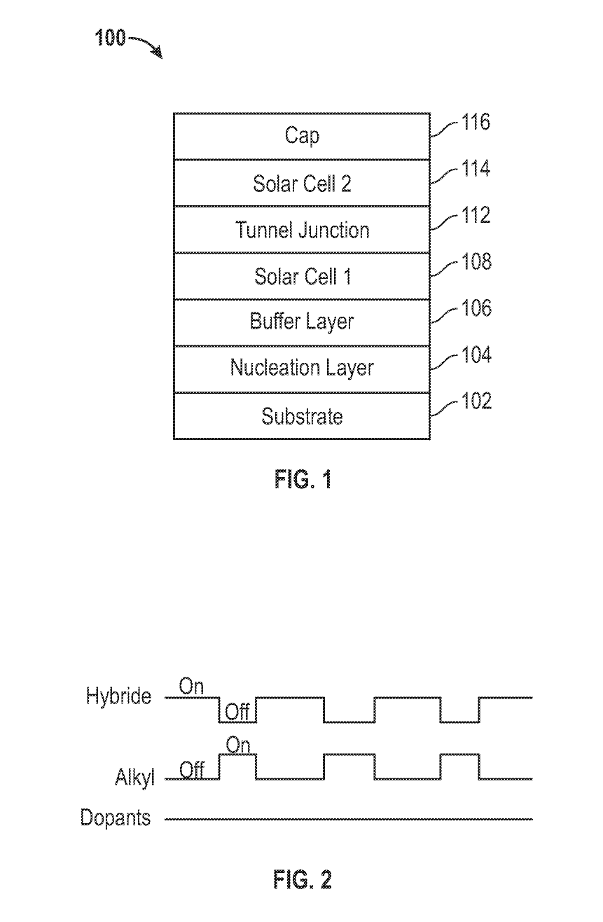

Referring to FIG. 1, a multi-solar cell structure 100 (hereinafter solar cell structure 100) is shown. The solar cell structure 100 may have a substrate 102. The substrate 102 may be formed of different materials. In accordance with one embodiment, gallium arsenide (GaAs), germanium (Ge), or other suitable materials may be used. The list of the above material should not be seen in a limiting manner. If a germanium (Ge) substrate is used, a nucleation layer 104 may be deposited on the substrate 102. On the substrate 102 or over the nucleation layer 104, a buffer layer 106 may then be formed.

A solar cell 108 may be formed on the buffer layer 106. The solar cell 108 may be formed of an n+ emitter layer and a p-type base layer. In accordance with one embodiment, Gallium (Ga) Indium (In) Phosphorus (P) may be used to form the solar cell 108. However, this should not be seen in a limiting manner.

A tunnel junction 112 may be formed between the solar cell 108 and another solar cell 114. The tunnel junction 112 may be used to connect the solar cell 114 and solar cell 108. The solar cell 114 may be similar to that of solar cell 108. The solar cell 114 may be formed of an n+ emitter layer and a p-type base layer. In accordance with one embodiment, Gallium (Ga) Indium (In) Phosphorus (P) may be used to form the solar cell 114. However, this should not be seen in a limiting manner. A cap layer 116 may be formed on the solar cell 114. The cap layer 116 serves as a contact for the solar cell structure 100. While FIG. 1 shows solar cells 108 and 114, additional solar cells and tunnel junctions may be used.

The quality of the tunnel junction 112 may be critical to keep the solar cell 114 on top of the tunnel junction 112 in high crystal quality. By providing a high quality tunnel junction 112, a higher tunnel junction current may be generated. This may enhance the efficiency of the solar cell structure 100.

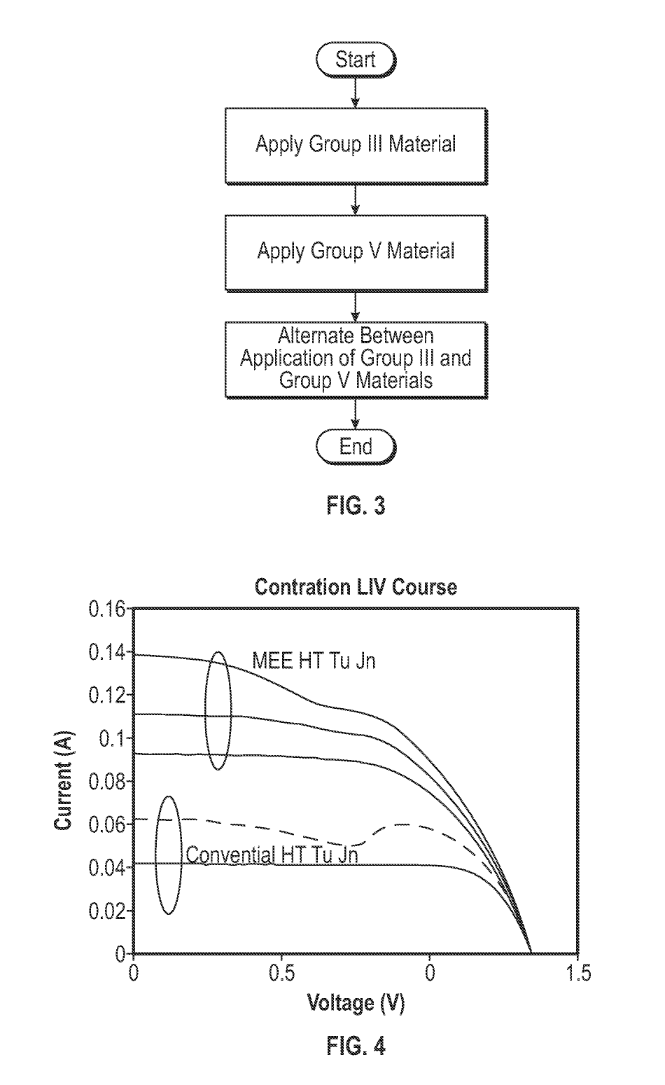

Presently, in existing high efficiency multi-junction solar cells lower temperatures may be used to achieve high doping concentration, particularly with the high bandgap materials like GaInP. Referring now to FIGS. 2 and 3, a method which may improve the quality of the tunnel junction 112 is disclosed. The method may use a migration enhanced epitaxial (MEE) method to form the tunnel junction 112.

MEE is a method of depositing single crystals. MEE may use group III and group V atoms alternatively, so that group III atoms have a longer diffusion length on the surface before reacting with group V atoms, and therefore achieve higher crystal quality. In forming the tunnel junction 112, different combinations of Group III and Group V elements listed in the periodic table may be used. Different combinations may be used based on lattice constant and bandgap requirements. Group III elements may include, but is not limited to: boran (B), aluminum (Al), gallium (Ga), indium (In), and thallium (Tl). Group V elements may include, but is not limited to: nitrogen (N), phosphorus (P), arsenic (As), antimony (Sb), and bismuth (Bi).

Migration of surface adatoms along the surface may be very important for growing high quality layers and atomically flat heterojunctions. MEE is using group III and group V modulation during the epitaxial which may enhance the group III atoms migrating on the substrate surface and therefore increase the quality. As shown in FIGS. 2 and 3, one alternates between the application of Group III and Group V materials. Thus, Group III material may first be applied to the TuJn layer 112. This may allow the Group III material a longer time to diffuse which may result in better crystal quality. Once the Group III materials are applied, Group V material may be applied. The alternation between application of Group III and Group V material continues until the tunnel junction 112 is complete. Different timeframes may be used when applying the Group III and Group V materials based on the materials used. Alternation times may range anywhere from 1 to 1000 seconds or more.

MEE may allow one to control the V/III ratio and enhance the doping, particularly the dopants like tellurium (Te), sulfur (S), carbon (C), etc., which take the group V atom site. MEE may be run at very low V/III ratio. Particularly when alkyl atoms paralyzed on the surface, Group V is not injected in the chamber, therefore the instant V/III ratio is very low and doping concentration is higher.

Referring to FIG. 4, concentration light I-V (LIV) curves are shown. In FIG. 4, the light I-V (LIV) performance of an MEE grown HT GaInP tunnel junction is shown versus a conventional epitaxy grown GaInP HT tune junction. While the LIV curves of the MEE grown HT GaInP tunnel junction are based on a single junction test structure, it may be clearly seen that the MEE HT TuJn shows higher tunneling current than the conventional epitaxy grown TuJn.

The existing high efficiency multi-junction solar cells normally use the lower temperature to achieve high doping concentration, particularly with the high bandgap materials like GaInP. MEE can be used for both high and low temperature growth of the TuJn layers and can achieve higher doping and higher quality TuJn layers while the conventional growth will compromise the quality to achieve high doping and therefore compromise the maximum tunneling current, and also the later layer quality. This invention can push the existing TuJn tunnel current to higher value and therefore will improve the efficiency.

While embodiments of the disclosure have been described in terms of various specific embodiments, those skilled in the art will recognize that the embodiments of the disclosure can be practiced with modifications within the spirit and scope of the claims.

What is claimed is:

1. A method of forming a tunnel junction in a solar cell structure comprising alternating between depositing a Group III material and depositing a Group V material on said solar cell structure.

2. The method of claim 1, wherein alternating between depositing a Group III material and depositing a Group V material further comprises:
depositing a Group III material on said solar cell structure; and
depositing a Group V material after deposition of said Group III material.

3. The method of claim 1, further comprising depositing said Group III material on a first solar cell device of said solar cell structure.

4. The method of claim 3, further comprising depositing said Group V material on said first solar cell device of said solar cell structure.

5. The method of claim 1, further comprising controlling a depositing ratio of said Group III material and said Group V material.

6. The method of claim 1, wherein alternating between depositing said Group III material further comprises depositing said Group III and said Group V materials for approximately 1 to 1000 seconds.

7. The method of claim 1, wherein said Group III materials comprises at least one of: boran (B), aluminum (Al), gallium (Ga), indium (In), and thallium (Tl).

8. The method of claim 1, wherein said Group V materials comprise at least one of: nitrogen (N), phosphorus (P), arsenic (As), antimony (Sb), and bismuth (Bi).

9. A method of making a solar cell structure comprising steps as claimed in claim 1.

10. The method of claim 9, further comprising the steps as claimed in claim 2.

11. The method of claim 9, further comprising the steps as claimed in claim 3.

12. The method of claim 9, further comprising the steps as claimed in claim 4.

13. The method of claim 9, further comprising the steps as claimed in claim 5.

14. A photovoltaic device, comprising:
a substrate;
a first solar cell device positioned above the substrate;
a contact positioned above the first solar cell; and
a tunnel junction positioned formed between the first solar cell and the contact, wherein the tunnel junction is formed by migration enhanced epitaxial (MEE).

15. A photovoltaic device in accordance with claim 14, wherein the tunnel junction is formed by said MEE method of alternating between depositing of Group III and Group V materials.

16. A photovoltaic device in accordance with claim 14, wherein the Group III materials comprise at least one of: boran (B), aluminum (Al), gallium (Ga), indium (In), and thallium (Tl).

17. A photovoltaic device in accordance with claim 14, wherein said Group V materials comprise at least one of: nitrogen (N), phosphorus (P), arsenic (As), antimony (Sb), and bismuth (Bi).

18. A photovoltaic device in accordance with claim 14, further comprising a buffer layer positioned between said substrate and said first solar cell device.

19. A photovoltaic device in accordance with claim 18, further comprising a nucleation layer positioned between said buffer layer and said substrate.

20. A photovoltaic device in accordance with claim 14, further comprising a second solar cell device positioned between said first solar cell device and said contact.
